(19) United States
(12) Patent Application Publication
(10) Pub. No.: US 2017/0288697 A1
(43) Pub. Date: Oct. 5, 2017

(54) LDPC SHUFFLE DECODER WITH INITIALIZATION CIRCUIT COMPRISING ORDERED SET MEMORY

(71) Applicant: Silicon Motion Inc., Hsinchu County (TW)

(72) Inventor: Yu-Luen Wang, Hsinchu City (TW)

(21) Appl. No.: 15/088,055

(22) Filed: Mar. 31, 2016

(51) Int. Cl. H03M 13/11

(52) U.S. Cl. CPC H03M 13/114; H03M 13/1128

(57) ABSTRACT

A low-density parity check (LDPC) decoding apparatus for performing shuffle decoding includes: an input wrapper, for receiving input data and padding the input data; an LDPC decoder, coupled to the input wrapper, for receiving the padded input data, performing a plurality of iterations of LDPC decoding upon the padded input data to generate channel values corresponding to the padded input data, and outputting a hard decision channel value in a final iteration; and an initialization circuit, coupled to the LDPC decoder, for receiving the input data in a first iteration of the plurality of iterations, storing the input data into an ordered set data, and immediately sending the ordered set data to the LDPC decoder.

### BACKGROUND OF THE INVENTION

### 1. Field of the Invention

This invention relates to low density parity check (LDPC) shuffle decoders, and more particularly, to LDPC shuffle decoders with an extra ordered set memory.

### 2. Description of the Prior Art

Low-density parity check (LDPC) decoders use a linear error correcting code with parity bits. Parity bits provide a decoder with parity equations which can validate a received codeword. For example, a low-density parity check is a fixed length binary code wherein all the symbols added together will equal zero.

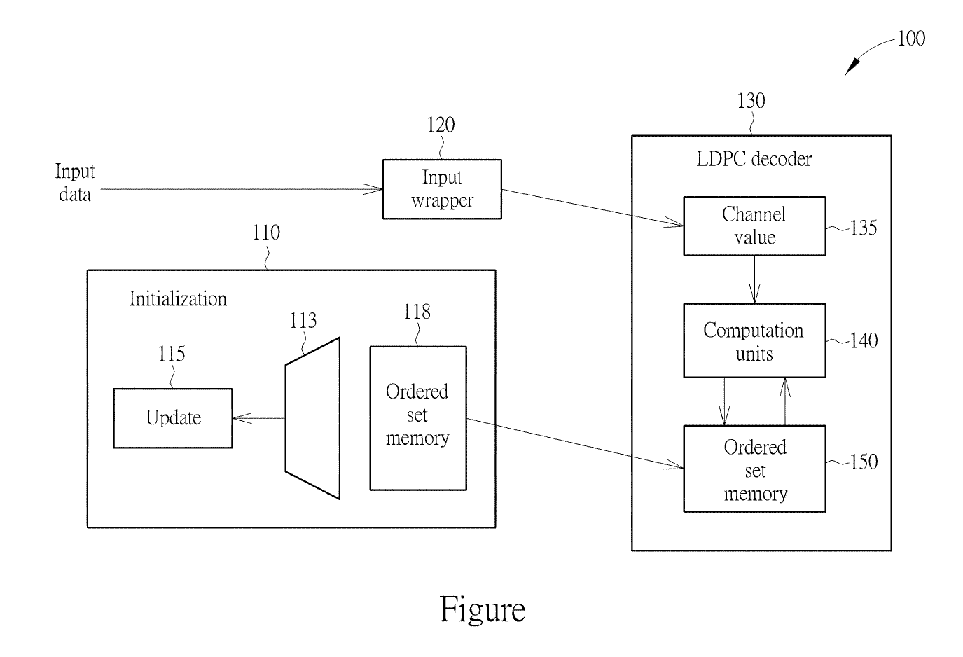

During encoding, all data bits are repeated and transmitted to encoders, wherein each encoder generates a parity symbol. Codewords are formed of k information digits and r check digits. If the length of the codeword is n then the information digits, k, will equal n−r. The codewords can be represented by a parity check matrix, which consists of r rows (representing equations) and n columns (representing digits), and is represented in FIG. 1. The codes are called low-density because the parity matrix will have very few ‘1’s in comparison to the number of ‘0’s. During decoding, each parity check is viewed as a single parity check code, and is then cross-checked with others. Decoding occurs at check nodes, and cross-checking occurs at variable nodes.

The check nodes are the number of parity bits, and the variable nodes are the number of bits in a codeword. If a code symbol is involved in a particular equation, a line is drawn between the corresponding check node and variable node. ‘Messages’, which are estimates, are passed along the connecting lines, and combined in different ways at the nodes. Initially, the variable nodes will send an estimate to the check nodes on all connecting lines containing a bit believed to be correct. Each check node then takes all the other connected estimates, makes new estimates for each variable node based on this information, and passes the new estimate back to the variable nodes. The new estimate is based on the fact that the parity check equations force all variable nodes connected to a particular check node to sum to zero.

Shuffle decoding is based on the above technique but works by using layered belief propagation. The parity matrix (also known as an H matrix) is divided into layers, and each layer is divided into sub-matrices. During decoding, the sub-matrices will be updated at the same time, such that the decoding algorithms are effectively shuffled. Each codeword length is divided into G groups. If a codeword has N bits then each group will have N/G bits. Updating within the groups occurs in parallel, i.e. there is parallel updating of the check nodes.

Initially, data is passed through an input wrapper and stored in a channel value memory. After an entire codeword is thus transmitted, the channel value memory can store estimates as V vectors, which are then updated in each iteration. As the algorithms are shuffled, barrel shifters are used to put modified channel values into a different order so they can be sent on a correct data path for storing in an ordered set memory.

The feature of shuffle decoding is that information is not used from the end of a previous iteration in a current iteration. Rather, information obtained in a current iteration is immediately used in the same iteration, thereby achieving the parallel updating. In a first iteration, however, data is input to the channel value memory but no information is present in the ordered set memory. Therefore, the first iteration is only used for storing data and initialization of parameters rather than for performing any error correction.

### SUMMARY OF THE INVENTION

With this in mind, it is an objective of the present invention to provide a system and method for shuffle decoding that can operate at maximum efficiency.

A low-density parity check (LDPC) decoding apparatus for performing shuffle decoding according to an exemplary embodiment of the present invention comprises: an input wrapper, for receiving input data and padding the input data; an LDPC decoder, coupled to the input wrapper, for receiving the padded input data, performing a plurality of iterations of LDPC decoding upon the padded input data to generate channel values corresponding to the padded input data, and outputting a hard decision channel value in a final iteration; and an initialization circuit, coupled to the LDPC decoder, for receiving the input data in a first iteration of the plurality of iterations, storing the input data into an ordered set data, and immediately sending the ordered set data to the LDPC decoder. The initialization circuit comprises: a multiplexer, for multiplexing the input data into the ordered set data; and an ordered set memory, for storing the multiplexed input data as the ordered set data and transmitting the ordered set data to the LDPC decoder, and the LDPC decoder comprises an ordered set memory for receiving the ordered set data from the ordered set memory of the initialization circuit.

A method for performing shuffle decoding in a low-density parity check (LDPC) decoding apparatus according to an exemplary embodiment of the present invention comprises: receiving input data comprising a plurality of codewords and error-correction information; padding the input data; performing a plurality of iterations of LDPC decoding upon the padded input data according to the error-correction information to generate channel values; outputting a hard decision channel value in a final iteration. In a first iteration, the method further comprises: utilizing an initialization circuit to store the input data into an ordered set data; and immediately sending the ordered set data to an LDPC decoder of the LDPC decoding apparatus; and

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The FIGURE is a block diagram of the shuffle decoder according to an exemplary embodiment of the present invention.

### DETAILED DESCRIPTION

In order to solve the problem of the prior art, the invention aims to use pre-update circuits.

Refer to the FIGURE, which illustrates a block diagram of a shuffle decoder 100 according to an exemplary embodiment of the present invention. The shuffle decoder 100 comprises an initialization circuit 110, which comprises an update circuit 115, an ordered set memory 118 and a multiplexer 113. The shuffle decoder 100 further comprises an input wrapper 120 and an LDPC decoder 130, which comprises a channel value memory 135, a computation unit block 140 and an ordered set memory 150.

The input wrapper 120 is for padding the codeword with sufficient bytes for the LDPC decoder 130. For example, the input data may contain 8 bytes, but the LDPC decoder 130 requires 48 bytes of data to operate. This is merely one example.

During a first iteration of decoding, the input data is input to the input wrapper 120, and padded. The padded data is then divided into groups G and stored to the channel value memory 135. In the conventional art, this is all that would occur in the first iteration. In the system of the exemplary embodiment, however, the input data is also input to the initialization circuit 110, where it will first be stored in the update circuit 115 and then multiplexed to the ordered set memory 118. As the bus width of the input data is much smaller than the bus width inside the LDPC decoder 130, the input data can be quickly stored in the ordered set memory 118. This allows the data stored therein to be passed to the ordered set memory 150 within the LDPC decoder 130 by the time the codeword has been stored in the channel value memory 135.

As shuffle decoding uses data obtained within a first iteration, the data stored in the channel value memory 135 can be updated within the first iteration.

Therefore, a number of useful iterations will be increased by 1, and the LDPC decoder can operate at near 100% efficiency, rather than 80%.

The multiplexer 113 in the initialization circuit 110 is for grouping the data together into an ordered set to be stored into the ordered set memory 118. In the first iteration, the sign of the data is directly input to the LDPC decoder 130. This is because it is harder to perform a one-shot update of the memory circuits. In the following iterations, the sign will be calculated by the LDPC decoder 135.

The circuitry required for the above is not complicated and can be easily implemented by one skilled in the art. As well as the initialization circuit 110, the computation unit 140 in the LDPC decoder 130 only requires extra adders for receiving the sign of the data in the first iteration. This is so that the sign and the received codeword can be used by the computation unit 140 to calculate channel values.

The present invention therefore improves the latency for an LDPC decoder by the simple addition of initialization circuits, ensuring that decoding can begin in a first iteration.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A low-density parity check (LDPC) decoding apparatus for performing shuffle decoding, comprising:
an input wrapper, for receiving input data comprising a plurality of codewords and error-correction information, and padding the input data;
an LDPC decoder, coupled to the input wrapper, for receiving the padded input data, performing a plurality of iterations of LDPC decoding upon the padded input data according to the error-correction information to generate channel values, and outputting a hard decision channel value in a final iteration; and
an initialization circuit, coupled to the LDPC decoder, for receiving the input data in a first iteration of the plurality of iterations, storing the input data into an ordered set data, and immediately sending the ordered set data to the LDPC decoder, so that the error-correction information can be used to perform LDPC decoding upon the padded input data in the first iteration.

2. The LDPC decoding apparatus of claim 1, wherein in the first iteration, a sign of the input data is directly input to the LDPC decoder.

3. The LDPC decoding apparatus of claim 1, wherein the initialization circuit comprises:
a multiplexer, for multiplexing the input data into the ordered set data; and
an ordered set memory, for storing the multiplexed input data as the ordered set data and transmitting the ordered set data to the LDPC decoder.

4. The LDPC decoding apparatus of claim 3, wherein the LDPC decoder comprises an ordered set memory for receiving the ordered set data from the ordered set memory of the initialization circuit.

5. The LDPC decoding apparatus of claim 4, wherein the ordered set memory of the LDPC decoder is initially empty before the first iteration, and is then updated in each subsequent iteration.

6. The LDPC decoding apparatus of claim 1, wherein a bus width of the input data is much smaller than a bus width inside the LDPC decoder.

7. A method for performing shuffle decoding in a low-density parity check (LDPC) decoding apparatus, comprising:
receiving input data comprising a plurality of codewords and error-correction information;
padding the input data;
performing a plurality of iterations of LDPC decoding upon the padded input data according to the error-correction information to generate channel values, wherein in a first iteration, the method further comprises:
utilizing an initialization circuit to store the input data into an ordered set data; and
immediately sending the ordered set data to an LDPC decoder of the LDPC decoding apparatus; and
outputting a hard decision channel value in a final iteration.

8. The method of claim 7, wherein in the first iteration, the method further comprises:
directly inputting a sign of the input data to the LDPC decoder.

9. The method of claim 7, wherein the step of storing the input data into an ordered set data further comprises:
multiplexing the input data into the ordered set data; and
storing the ordered set data into an ordered set memory of the initialization circuit.

10. The method of claim 9, wherein the LDPC decoder comprises an ordered set memory for receiving the ordered set data from the ordered set memory of the initialization circuit.

11. The method of claim 10, wherein the ordered set memory of the LDPC decoder is initially empty before the first iteration, and is then updated in each subsequent iteration.

12. The method of claim 7, wherein a bus width of the input data is much smaller than a bus width inside the LDPC decoder.
